(19) United States
(12) Patent Application Publication
(10) Pub. No.: US 2016/0073539 A1
(43) Pub. Date: Mar. 10, 2016

(54) FLEXIBLE PRINTED CIRCUIT BOARD ASSEMBLY FOR ELECTRONIC DEVICES

(71) Applicant: DIMENSIONAL INDUSTRIES, INC., San Diego, CA (US)

(72) Inventors: Jonathan Daniel Driscoll, San Diego, CA (US); Aaron Tynes Hammack, Berkeley, CA (US)

(21) Appl. No.: 14/846,718

(22) Filed: Sep. 4, 2015

Related U.S. Application Data
(60) Provisional application No. 62/046,642, filed on Sep. 5, 2014.

(51) Int. Cl. H05K 7/14; H02M 1/32; G01L 1/18; H02M 7/219

(52) U.S. Cl. CPC H05K 7/1422; H02M 7/219; H02M 1/32; G01L 1/18

(57) ABSTRACT

A flexible printed circuit board assembly for electronic devices is disclosed. An example embodiment includes: a force sense resistor (FSR) comprising: at least one flexible common reference trace; at least one flexible conductive trace having a varying-width pattern and being placed adjacent to the at least one flexible common reference trace, the conductive trace being at a varying distance from the common reference trace relative to a location along the FSR; and a flexible piece of piezoresistive material covering the common reference trace and the conductive trace, the flexible piece of piezoresistive material being configured to produce a measurable electrical resistance relative to a distance between the conductive trace and the common reference trace as pressure is applied to the piezoresistive material, the FSR enabling detection of pressure levels and locations along the FSR.

### PRIORITY PATENT APPLICATION

The present application is non-provisional patent application drawing priority from co-pending U.S. provisional patent application Ser. No. 62/046,642; filed Sep. 5, 2014. This present non-provisional patent application draws priority from the referenced patent application. The entire disclosure of the referenced patent application is considered part of the disclosure of the present application and is hereby incorporated by reference herein in its entirety.

### TECHNICAL FIELD

The present disclosure relates to flexible printed circuit boards (flexPCBs) for controlling electronic devices, and more particularly to methods of designing flexPCBs and assembling electronic devices.

### BACKGROUND

Assembly of completed electronic devices can be a time-consuming process, involving soldering and placing many individual wires and electronics components. Frequently, flexible printed circuit boards (flexPCBs) are used to simplify this process, since they can incorporate wiring, solder points, electronics, and even heaters and sensors in a thin, flexible sheet of circuitry, which is custom-designed and sized for a particular device.

### BRIEF DESCRIPTION OF THE DRAWINGS

The present disclosure, in accordance with one or more various embodiments, is described in details with reference to the following figures. The drawings are provided for purposes of illustration only and merely depict one exemplary embodiment of the disclosure. These drawings are provided to facilitate the reader's understanding of the disclosure and should not be considered limiting the breadth, scope, or applicability of the disclosure. It should be noted that for clarity and ease of illustration these drawings arc not necessarily made to scale.

FIG. 1 is an exemplary electronic device, according to an embodiment of the present disclosure

FIG. 2 is an exemplary frame housing components of an electronic device, according to an exemplary embodiment.

FIG. 3 is an exemplary flexPCB, according to an exemplary embodiment.

FIG. 4 is an exemplary flexPCB connected to electronic components, according to an exemplary embodiment.

FIG. 5 is an exemplary frame housing electronic components, and a flexPCB, according to an exemplary embodiment.

FIG. 6 is an exemplary flexPCB wrapped around a frame, and a piezoresistive material, according to an exemplary embodiment.

FIG. 7A is an exemplary motif of two traces and a common reference trace of a flexPCB, according to an exemplary embodiment.

FIG. 7B is an exemplary flexPCB with repeated traces and common reference trace, according to an exemplary embodiment.

FIG. 8 is an exemplary H-bridge circuit diagram, according to an exemplary embodiment.

### DETAILED DESCRIPTION

The following description is presented to enable a person of ordinary skill in the art to make and use the invention. Descriptions of specific devices, techniques, and applications are provided only as examples. Various modifications to the examples described herein will be readily apparent to those of ordinary skill in the art, and the general principles defined herein may be applied to other examples and applications without departing from the spirit and scope of the disclosure. Thus, the present disclosure is not intended to be limited to the examples described herein and shown, but is to be accorded the scope consistent with the claims.

The word “exemplary” is used herein to mean “serving as an example or illustration.” Any aspect or design described herein as “exemplary” is not necessarily to be construed as preferred or advantageous over other aspects or designs.

Moreover, it should be understood that the specific order or hierarchy of functional steps in the processes disclosed herein is an example of exemplary approaches. Based upon design preferences, it is understood that the specific order or hierarchy of steps in the processes may be rearranged while remaining within the scope of the present disclosure.

In this disclosure, the use of a custom flexPCB is described for easing the assembly of a personal massager product, for example. One of ordinary skill in the art would realize that various electronic devices other than personal massagers could be implemented, within the scope of the inventive features described herein. In addition to simplifying manufacture and assembly, the flexPCB is designed so that one layer (e.g., inner layer) supports power, wiring busses, and optional traces for a heater, and another layer (e.g., outer layer) supports exposed conductive traces for incorporating pressure sensors. Alternatively, the flexPCB can be designed so that one layer (e.g., outer layer) supports power, wiring busses, and optional traces for a heater, and another layer (e.g., inner layer) supports exposed conductive traces for incorporating pressure sensors.

In addition, the flexPCB can be created so that supporting electronics circuitry is incorporated through the design as well. For instance, circuitry such as motor driver, accelerometer, microcontroller, and wireless (or wired communications) can be populated onto the same PCB, possibly on a portion of stiffened board according to an example.

Further, a “multilevel” board can be created, by folding portions of the flexible board over on top of itself, to make a more compact, three dimensional arrangement of circuitry. Additional components, such as buttons for user input, wiring for charge connectors, battery terminal connections, and electromagnetic interference (EMI) filtering components (typically LC filtering), may all be on the same board, greatly simplifying assembly, and allowing for configurations which would be difficult to implement in discrete, separate circuit boards.

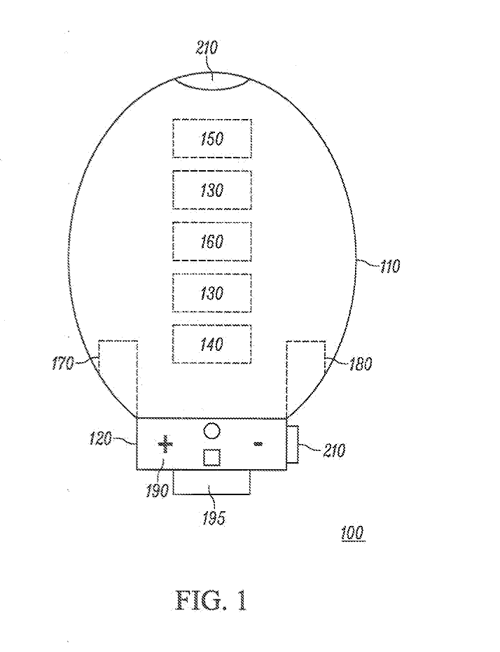

FIG. 1 illustrates an exemplary electronic device, which could be a personal massaging device, according to an embodiment of the present disclosure. A personal massaging device is referred to herein as one possible electronic device; however, it should be clear to one of ordinary skill in the art that various other devices could be similarly employed to realize the benefits of novel features described herein. As shown in FIG. 1, the personal massaging device 100 (also called “personal massager”) may include a main body 110 that can house electronics and power source(s) 160 (e.g., a battery) required to operate the device. Main body 110 can include one or more vibrator units 130, such as vibration motors, configured to cause the device 100 to vibrate, along with one or more sensors 140 (which could be any combination of accelerometers, pressure sensors, biopotential sensors, biofeedback sensors, gyroscopes, compasses, electrocardiogram (EKG/ECG) devices, electromyography (EMG) devices, electroencephalography (EEG) devices, galvanic skin response sensors, blood oxygen level sensors, temperature sensors, microphones, respiration sensors, and/or optical sensors). In a particular embodiment, the sensors 140 can include a plethysmograph, photoplethysmograph, or a pulse oximeter. A plethysmograph is an instrument for measuring changes in volume within an organ or whole body (usually resulting from fluctuations in the amount of blood or air it contains). A photoplethysmograph (PPG) is a plethysmograph that uses optical techniques. A pulse oximeter measures oxygen saturation level (SpO2) and heart rate and is also a PPG. It can measure the change in the volume of arterial blood with each pulse beat. This change in blood volume can be detected in peripheral parts of the body such as the fingertip or ear lobe using a technique called photoplethysmography. The pulse oximeter that detects the signal is called a plethysmograph. The sensor data produced by the sensors 140 can be used to detect, among other parameters. an orientation and movement of the device 100, angular positioning of the device 100, a direction of movement of the device 100, a velocity and/or an acceleration of the device 100, an orientation, rotation, and/or inclination of the device 100, the blood oxygen saturation level of a user of the device 100, the heart rate of a user of the device 100, and any of a variety of parameters that can be obtained or derived from the sensor data. Main body 110 can further include a heating unit 150 configured to heat the personal massaging device 100.

Personal massaging device 100 can include a handle 120 for the user to hold. Handle 120 can house one or more buttons 190, or other similar control elements, which allow the user to adjust various characteristics of the output of the personal massaging device 100, such as vibration intensity, temperature, or which on-board processing logic is in control of the input-output relationship, etc. The locations of the various components, the handle 120 and main body 110 are depicted in FIG. 1 as merely one example, and various configurations, as well as combinations of hardware, may be employed.

Main body 110 can further include a memory storage unit 170 configured to store predefined modes, or outputs, which can cause the vibrator unit(s) 130 (including one or more motors), lighting unit(s), heating unit(s) 150 and/or audio unit(s) to activate dependent upon various inputs provided by sensor units 210. As described herein, according to an embodiment, biofeedback signal obtained by sensor units can be used to determine which of the one or more various modes, or outputs, the personal massaging device 100 can produce.

Main body 110 can also have a transceiver unit 195 configured to receive wireless signals transmitted by sensor units via Bluetooth, cellular connectivity, WiFi connectivity or any other similar wireless communication technique. One of ordinary skill in the art would realize that any conventional hard-wired connectivity can similarly be utilized, without departing from the scope of the present disclosure.

A control unit 180 may be employed within main body 100. The control unit may be a programmable processor configured to control the operation of the personal massaging device 100 and its components. For example, the control unit 180 may be a microcontroller (“MCU”), a general purpose hardware processor, a digital signal processor (“DSP”), application specific integrated circuit (“ASIC”), field programmable gate array (“FPGA”) or other programmable logic device, discrete gate or transistor logic, discrete hardware components, or any combination thereof designed to perform the functions described herein. A general-purpose processor can be a microprocessor, but in the alternative, the processor can be any processor, controller, or microcontroller. A processor can also be implemented as a combination of computing devices, for example, a combination of a and a microprocessor, a plurality of microprocessors, one or more microprocessors in conjunction with a DSP core, or any other such configuration.

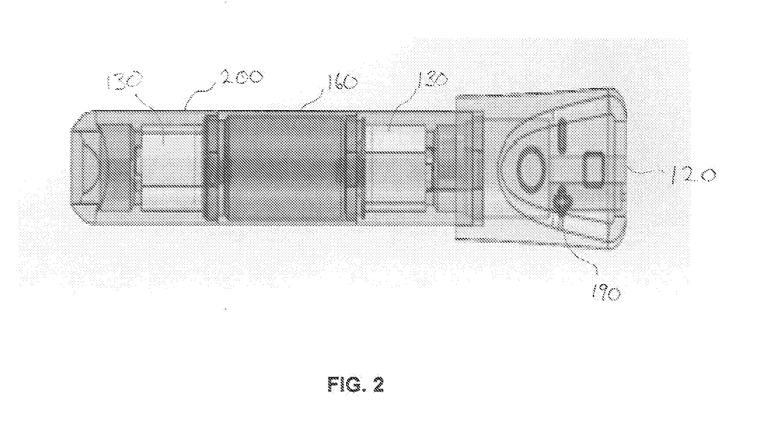

FIG. 2 shows an exemplary frame 200 securing the components within main body 110 (not shown), described above, according to an embodiment. In one example, the frame 200 can be formed by three-dimensional (3D) printed acrylonitrile butadiene styrene (ABS) plastic. Various other techniques and/or materials could be implemented to form the frame 200. For example, a variety of materials other than ABS plastic can be used with 3D printers. Furthermore, conventional techniques other than 3D printing can be used to fabricate frame 200. Frame 200 can be eventually overmolded with main body 110, which is further described below. Frame 200 as shown in FIG. 2 depicts an exemplary positioning of battery 160 and vibrator unit motors 130, along with handle 120, which can be formed of the same material or a different material, such as silicon. Handle 120 can be placed over the end of frame 200, such that buttons 190 and other control elements can interact with the components housed by frame 200.

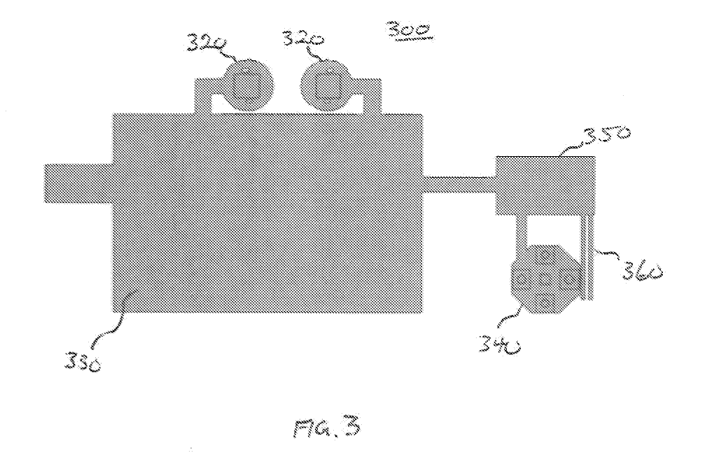

FIG. 3 depicts an exemplary geometry of flexPCB wrap 300 including circuitry configured to interact with the components of device 100 held by frame 200, according to an embodiment. FlexPCB 300, according to the present embodiment, can wrap around frame 200 in a manner that allows contact and interaction with components housed by frame 200, such as battery 160, vibrator unit motor(s) 130, etc. It will be apparent to those of ordinary skill in the art in view of the disclosure herein that flexPCB 300 can be configured in a variety of different geometries.

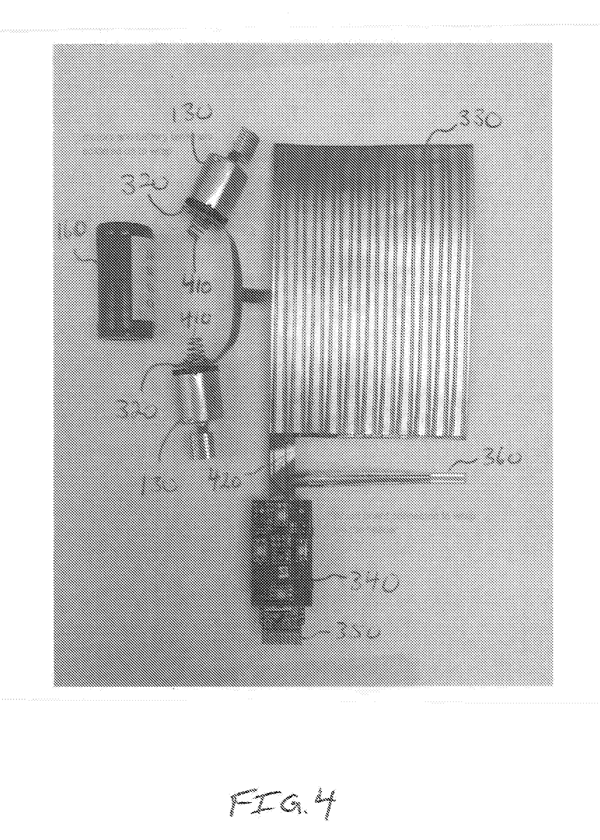

FlexPCB wrap 300 can include connectors 320, which allow electrical connection to the one battery 160 and/or motors for vibrator unit(s) motors 130, for example, to be controlled. As further described below, connectors 320 can be double-sided, such that a front side of connectors 320 connects (e.g., by soldering) to corresponding connectors of vibrator unit motor(s) 130 to provide power thereto. The back side of connectors 320 can include spring or pad connectors (or any other connectors) to connect to either pole of battery 160. (see, e.g., FIG. 4).

The circuitry section 330 of flexPCB wrap 300 can include wiring for controlling components within device 100, along with the power bus and traces for force-sense resistors (described in further detail below). Section 330 of flexPCB 300 can include heater traces configured to generate heat to be experienced by the user of device 100. According to this embodiment, wire tracings can be spaced and sized to create a total electrical resistance on the order of a few ohms. For instance, the heater may be designed to generate a few watts per square inch. To simplify wiring, according to one example, the positive end of the heater trace can be connected directly to the positive end of the battery 160, and the negative end of heater trace connected to the controlling electronics, which can also be placed on the flexPCB 300. Typically, this can be a low on resistance power metal-oxide-semiconductor field-effect transistor (MOSFET), configured as a low-side switch, which can either return the heater current to ground, thus enabling heat, or create a high-impedance block of the heater current, thus turning it off. Note that a temperature sensing component, such as a thermister or discrete integrated circuit (IC), can be mounted on the flexPCB, close to the heater traces. Measurements from the temperature sensor can be read by control unit 180, for example, which allows the heater to be run in a closed-loop, thermostat type of mode. In an exemplary embodiment, the temperature could be regulated to be close to or somewhat above body temperature. More advanced processing logic, such as running the heat slightly higher initially, to allow the surrounding to warm up, can also be implemented.

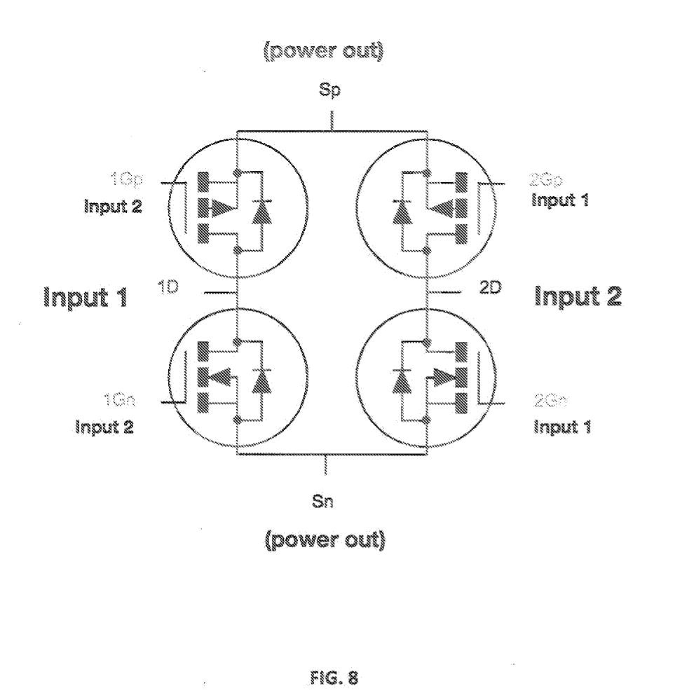

Moreover, motors 130 can be driven by a bipolar signal from a motor driver, and the power and ground are also brought to the controlling electronics, e.g., located on sections 340 or 350, or any section of flexPCB 300. Each motor 130 is driven with a low-side drive (each with a half of an H-Bridge circuit, as described below with respect to FIG. 8). This greatly reduces wiring requirements, because only one wire is run for the motors 130, rather than two, and less current must pass through the main power bus as well.

The smaller rectangular portion 350 and octagonal portion 340 can include circuitry for buttons 190 (shown in portion 340) and wiring for electrically coupling the buttons 190 with wiring and the power bus in section 330. Strips 360 include wiring connected to charge pins, which allow charge current to flow into the device 100 (described in further detail below). In alternative embodiments, the device 100 can be inductively charged without the need for charge pins or the related wiring. As shown in more detail below, sections 350 and/or 340 can be included as a more rigid circuit board communicatively coupled to section 330 via a flat cable connector 420, for example (see e.g., FIG. 4 below). The overall geometry of each section is shown for exemplary purposes, and one of ordinary skill in the art in view of the disclosure herein would realize that various other geometric designs could be used to form flexPCB wrap 300.

FIG. 4 shows an exemplary flexPCB wrap 300 electrically connected to vibrator unit motors 130 via the front of connectors 320, according to an exemplary embodiment. In this example, motors 130 are soldered to the front of connectors 320, while the back sides of connectors 320 include spring connectors 410 for contacting either end (i.e., positive and negative terminals) of battery 160. Connectors 320 can include stiffened portions capable of supporting electromagnetic interference (EMI) filtering capacitor(s) and inductor(s) (not shown) mounted closely to motors 130. The embodiment depicted in FIG. 4 also shows exemplary sections 340 and 350, which include rigid circuit boards coupled to section 330 via a flat cable connector 420. As shown by the design of the flexPCB wrap 300 of FIGS. 3 and 4, the connectors 320 can be housed within frame 200, when connected to motors 130 and contacting battery 160, while the remaining sections can he wrapped around the outside of frame 200.

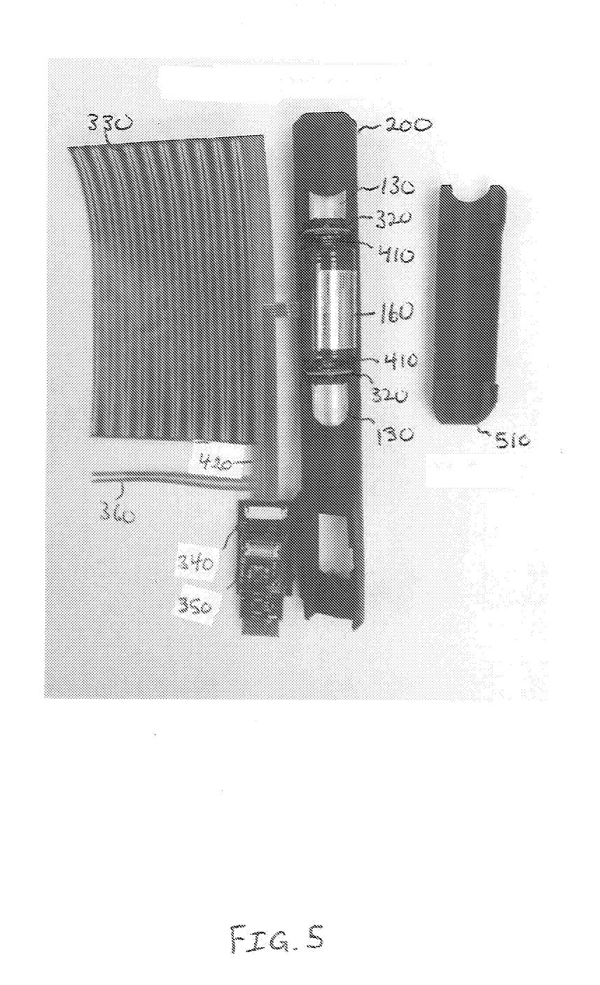

FIG. 5 shows an exemplary frame 200 housing battery 160 and motors 130 electrically connected to connectors 320 of flexPCB wrap 300. As shown in FIG. 5, connectors 320 can fit between the motors 130 and battery 160, while being housed in frame 200. The remaining sections of flexPCB wrap 300 remain connected to connectors 320 (e.g., via a cable connector), but are outside of frame 200. According to certain embodiments, some or all of the components housed in frame 200 can be glued, or otherwise secured, therein in order to prevent shifting within the frame 200.

Once all components necessary are housed in frame 200, cover 510, which can also be a 3D-printed ABS plastic fitted part (or any other type of material or fabricated using other techniques), can be used to cover the components within frame 200 and device 100. Cover 510 can be glued or otherwise attached to frame 200. The size and shapes of the frame 200 and cover 510 could vary depending on the particular design of device 100. The depicted embodiment is merely provided as one possible example. The depicted size(s) and shape(s) of any component should not be interpreted as limiting the inventive features described herein in any way.

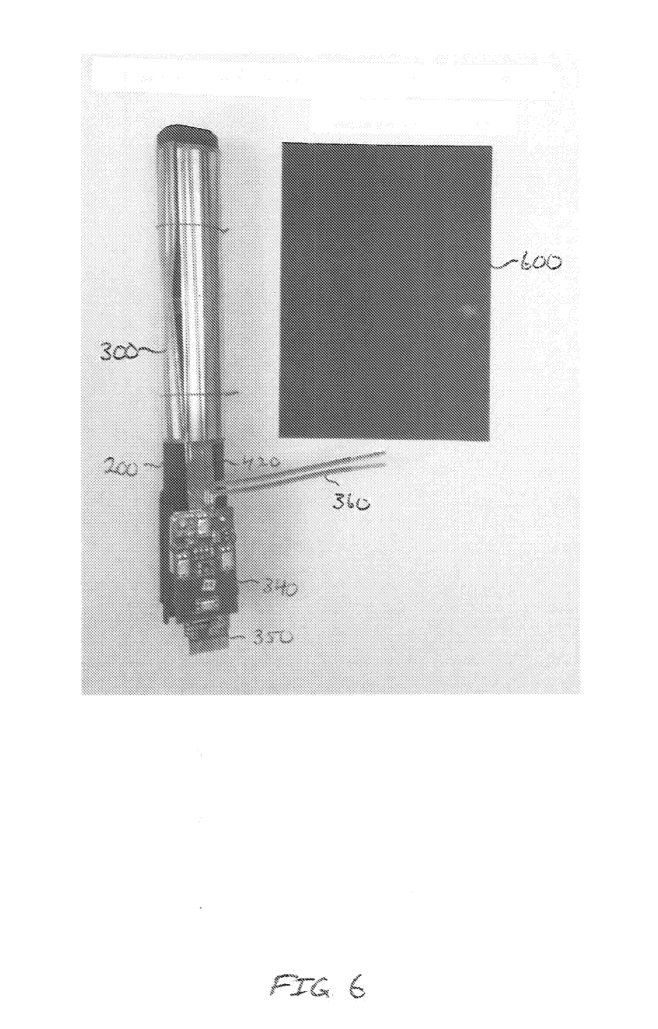

Once the cover 510 is attached to frame 200, the remaining flexPCB wrap 300 that is not housed in frame 200 can be wrapped around the enclosed frame 200, as shown in FIG. 6. The flexPCB 300 can be held around frame 200 using double-sided tape, for example, or any other adhesive mechanism. Thereafter, according to an embodiment, a piezoresistive material 600 (e.g., velostate) can be wrapped to cover flexPCB 300, in order to create a pressure sensor, as described in greater detail below. The circuit boards of portions 340 and 350 can be placed into the desired position within frame 200, which can have an opening such that buttons 190 can be pressed to control components within device 100, via circuitry on portions 340 and 350, for example.

After the flexPCB 300 is secured around frame 200, the main body 110 can be formed to complete the device 100. Main body 110, according to this exemplary embodiment, is an overmolding achievable by suspending the frame 200 (populated with motor(s) 130, battery 160, circuit boards, sensors etc.) wrapped with flexPCB 300 inside a 3D printed plastic mold. The mold can be filled with a high quality, biocompatible, room temperature vulcanization, two part liquid silicone (e.g., RTV-2 silicone). Frame 200 can be suspended by two or more pins protruding from the base (i.e., button of handle 120), for example, which allows for correct placement of frame 200 within the mold. After curing, the mold can be removed by cutting it off, or any other method, and the one or more pins can be pressed into device 100. This process allows for a completely seamless, finished overmold.

As shown in FIGS. 4 and 5, section 330 of flexPCB 300 may include a specific geometry of circuit traces utilized to measure a change in resistance of the piezoresistive material 600 as pressure is applied by a user of device 100, thus creating a force sensor resistor (FSR). According to one example, by creating at least two closely-positioned sets of circuit traces on the flexPCB 300, one for each side of the FSR, and covering these traces with piezoresistive material 600, an FSR is created. This technique can be extended to create multiple, nearly overlapping, pressure sensing regions, while still using only one layer of traces.

The conductance of the FSR is a monotonically increasing function of the pressure, expressed in general as:

g=f(p) Eq. (1)

typically, a linear relationship is assumed for simplification, such that:

g=a*p Eq. (2)

where g is the conductance, p is the pressure, and a is a constant of proportionality. Because the equation is monotonic, it can be inverted to give:

p=f¹(g) Eq. (3)

The relationship between the pressure and measured conductance is dependent on the geometry of the traces. For example, traces spaced farther apart will result in a lower conductance measurement for the same applied pressure.

In a simplified/ideal case, where the thickness of the piezoresitive layer is negligible compared to the spacing of the traces, the conductance is directly proportional to the width, w, of the FSR traces and indirectly proportional to the spacing between the traces, such that:

g=a′*w*p Eq. (4)

By varying the spacing between the traces, it is possible to change the sensitivity (conduction as a function of pressure) in various regions. Note that it is possible to run multiple, independent pressure sensors on a single flexPCB layer by adding a third trace to the PCB. In an embodiment, this could be wired so that one trace is a shared ground, whereas the other two traces can be wired to measure the resistance from that trace to ground.

The above equations can be used to create a geometry, where one set of traces has increased pressure sensitivity for a first sensor in the front of the device, and the other set of traces has increased sensitivity for a second sensor in the rear of the device. By carefully constructing the traces, a relationship can be formed whereby the total pressure measured by the two sensors will always sum to the total applied pressure.

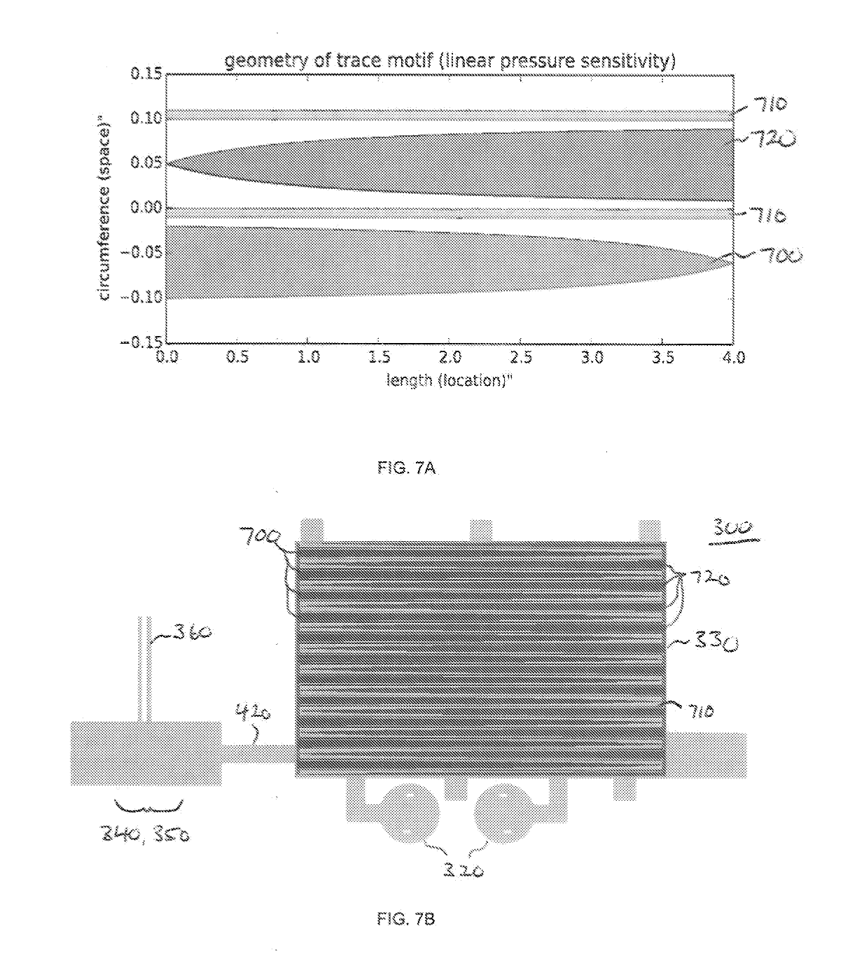

FIG. 7A is a single motif of a geometry of traces used to create an FSR in an example embodiment. At a first side of the geometry of the example embodiment, a first trace 700 gets closer to a common reference trace 710 (e.g., aground trace) while the second trace 720 gets farther away from ground 710. At a second side of the geometry of the example embodiment, the first trace 700 gets farther away from the common reference trace 710 while the second trace 720 gets closer to the ground 710. The exact spacing can be created so that the sensitivity of one trace increases linearly from 0% to 100%, whereas the other decreases linearly from 100% to 0%. In alternative embodiments, the spacing can be created so that the sensitivity of the traces increases or decreases non-linearly.

FIG. 7B shows flexPCB 300 including FSR traces, as described above with reference to FIG. 7A. In FIG. 7B, the sample motif of FIG. 7A including first trace 700 and second trace 720 is repeated multiple times. Common reference trace 710 is patterned between the first trace 700 and second trace 720.

By calculating the pressure differences measured at the two traces 700 and 720, it is possible to identify the particular location on the overall trace pattern at which the pressure is applied. For example, as explained earlier, traces spaced farther apart will result in a lower conductance measurement for the same applied pressure. If a trace geometry that varies the distance between traces is used (e.g., as shown in FIG. 7A), similar applied pressures will result in different conductance measurements depending on the particular location along the trace where the pressure is applied. By calculating the differences between the sensed pressures at two or more adjacent traces, a location of the applied pressure along each trace may be inferred.

In alternative embodiments, a single trace configured in a particular geometry can be placed adjacent to a common reference trace and used to vary the conductance (linearly or non-linearly) relative to pressure applied at different locations along the flexPCB. In other alternative embodiments, multiple (e.g., more than two) traces configured in particular geometries can be placed adjacent to each other and to a common reference trace and used to vary the conductance (linearly or non-linearly) between the multiple traces relative to pressure applied at different locations along the flexPCB. still other alternative embodiments, the common reference trace itself can be configured in a particular geometry to further vary the conductance (linearly or non-linearly) relative to pressure applied at different locations along the flexPCB. As such, the use of any number of traces in any linear or non-linear geometry for detecting pressure levels and locations along a flexPCB is within the scope of the embodiments described herein.

Supporting electronics for the FSR can be included in the handle 120 (e.g., on the circuit board(s) of sections 340/350), and/or the inner layer of the flexPCB 300, for example. Also, the flexPCB 300 can be constructed with headers and solder points, for ease of prototyping (i.e., the electronics can be changed, without remanufacturing the wrap).

In order to charge the device 100, a voltage is connected to charge pins, coupled to charge strip 360, at any location on device 100. In the case of a USB power supply, for example, this voltage can be 5V. To allow the charger to connect in either polarization, a full-bridge rectifier can be incorporated inside device 100. However, a full-bridge rectifier would require two diode drops, resulting in approximately a one volt potential drop across the diodes. This is problematic for charging a lithium battery, for example, which may need to charge to 4.2 V, or higher. A voltage source of 4V would not work without additional circuitry (e.g., a voltage step-up), which adds expense, heat, and EMI.

One solution is to modify a full-bridge rectifier to use metal-oxide-semiconductor field-effect transistors (MOSFETS), rather than diodes, as shown in FIG. 8. The full-bridge rectifier of FIG. 8 is an improvement of a reverse battery protection circuit, which uses only one MOSFET. Instead, the depicted rectifier includes four MOSFETS in series pairs, connected in a closed loop configuration. Implementing a full-bridge rectifier as provided in FIG. 8 (i.e., with n and p type MOSFETS being turned on and off), a device can be powered/charged using a charging device, regardless of polarity. In other words, a charger could be connected in either polarization to the charging pins of device 100 in order to charge/power the device 100.

According to one embodiment, the rectifier of FIG. 8 can also include one or more protection diodes in parallel with one or more gates of the MOSFETS, respectively, to prevent them from being damaged by static discharge.

As a result of the features described in this disclosure, a custom flexPCB is provided for simplified assembly electronic devices. One layer of the flexPCB is designed to support power, wiring busses, and optional traces for a heater, and another layer supports exposed conductive traces for incorporating pressure sensors, for example. Various other circuitry can be populated onto the same PCB, or possibly on a portion of stiffened board, according to an example. The flexPCB can be utilized to form an FSR customizable to detect pressure at various detectable portions of device 100.

Further, charging of device 100 can be achieved using a modified full-bridge rectifier using MOSFETS rather than diodes, in order to allow connectivity to a charging device in either polarization.

The various example embodiments disclosed herein include the following example embodiments.

A method of charging a lithium battery, comprising: connecting at least four metal-oxide-semiconductor field-effect transistors (MOSFETs) in series pairs; connecting a voltage of either polarity to the input of the at least four MOSFETs; and outputting to charge circuitry of the lithium battery a direct current (DC).

The method as claimed above further comprising: preventing status discharge by connecting at least one protection diode in parallel with a gate of at least one of the at least four MOSFETs.

While various embodiments of the invention have been described above, it should be understood that they have been presented by way of example only, and not by way of limitation. Likewise, the various diagrams may depict an example architectural or other configuration for the disclosure, which is done to aid in understanding the features and functionality that can be included in the disclosure. The disclosure is not restricted to the illustrated example architectures or configurations, but can be implemented using a variety of alternative architectures and configurations. Additionally, although the disclosure is described above in terms of various exemplary embodiments and implementations, it should be understood that the various features and functionality described in one or more of the individual embodiments are not limited in their applicability to the particular embodiment with which they are described. They instead can be applied alone or in some combination, to one or more of the other embodiments of the disclosure, whether or not such embodiments are described, and whether or not such features are presented as being a part of a described embodiment. Thus the breadth and scope of the present disclosure should not be limited by any of the above-described exemplary embodiments.

Terms and phrases used in this document, and variations thereof unless otherwise expressly stated, should be construed as open ended as opposed to limiting. As examples of the foregoing: the term “including” should be read as meaning “including, without limitation” or the like; the term “example” is used to provide exemplary instances of the item in discussion, not an exhaustive or limiting list thereof; and adjectives such as “conventional,” “traditional,” “normal,” “standard,” “known”, and terms of similar meaning, should not be construed as limiting the item described to a given time period, or to an item available as of a given time. But instead these terms should be read to encompass conventional, traditional, normal, or standard technologies that may be available, known now, or at any time in the future. Likewise, a group of items linked with the conjunction “and” should not be read as requiring that each and every one of those items be present in the grouping, but rather should be read as “and/or” unless expressly stated otherwise. Similarly, a group of items linked with the conjunction “or” should not be read as requiring mutual exclusivity among that group, but rather should also be read as “and/or” unless expressly stated otherwise. Furthermore, although items, elements or components of the disclosure may be described or claimed in the singular, the plural is contemplated to be within the scope thereof unless limitation to the singular is explicitly stated. The presence of broadening words and phrases such as “one or more,” “at least,” “but not limited to”, or other like phrases in some instances shall not be read to mean that the narrower case is intended or required in instances where such broadening phrases may be absent.

Furthermore, although individually listed, a plurality of means, elements or method steps may he implemented by, for example, a single unit or processing logic element. Additionally, although individual features may be included in different claims, these may possibly be advantageously combined. The inclusion in different claims does not imply that a combination of features is not feasible and/or advantageous. Also, the inclusion of a feature in one category of claims does not imply a limitation to this category, but rather the feature may be equally applicable to other claim categories, as appropriate.

What is claimed is:

1. A force sense resistor (FSR) comprising:
at least one flexible common reference trace;
at least one flexible conductive trace having a varying-width pattern and being placed adjacent to the at least one flexible common reference trace, the conductive trace being at a varying distance from the common reference trace relative to a location along the FSR; and
a flexible piece of piezoresistive material covering the common reference trace and the conductive trace, the flexible piece of piezoresistive material being configured to produce a measurable electrical resistance relative to a distance between the conductive trace and the common reference trace as pressure is applied to the piezoresistive material, the FSR enabling detection of pressure levels and locations along the FSR.

2. The FSR of claim 1 being further configured to include a plurality of flexible conductive traces each having a varying-width pattern and being placed adjacent to each other and the at least one flexible common reference trace, the plurality of flexible conductive traces each being at a varying distances from the common reference trace relative to a location along the FSR, the plurality of conductive traces being separated by a predetermined distance corresponding to a determinable sensitivity.

3. The FSR of claim 2, wherein the predetermined distance is such that a conductive trace of one of the plurality of flexible conductive traces can fit completely between two others of the plurality of flexible conductive traces.

4. The FSR of claim 2, wherein a sum of the conductance determined for each of the plurality of flexible conductive traces is the same at all points along the FSR.

5. A circuit comprising:
a modified full-bridge rectifier including at least four metal-oxide-semiconductor field-effect transistors (MOSFETs) in series pairs, connected in a closed loop configuration, the circuit being configured to allow charging of a battery connected in either polarization.

6. The circuit of claim 5 further comprising:
at least one protection diode in parallel with a gate of at least one of the at least four MOSFETs to prevent damage from electrostatic discharge (ESD).

7. An apparatus comprising:
a frame;
a flexible printed circuit board (flex PCB) wrapped around at least a portion of the frame, wherein the flex PCB includes a first layer comprising power and wiring busses, and a second layer including one or more conductive traces, wherein the flex PCB includes at least one header electrically coupled to hardware held by the frame; and
a piezoresistive material covering the flexible printed wrap.

8. The apparatus of claim 7, wherein the hardware held by the frame includes at least one of a battery, one or more vibrator units, one or more user-input buttons, and one or more electromagnetic interference filtering components.

9. The apparatus of claim 7, wherein the one or more conductive traces include at least one of a force sensor resistor and a heater trace.

10. The apparatus of claim 7, wherein the frame is a three-dimensionally printed frame.

11. The apparatus of claim 7, wherein the flex PCB includes a rigid circuit board.

12. The apparatus of claim 7, wherein the header is electrically coupled to a circuit board.
